(19) United States
(12) Patent Application Publication
(10) Pub. No.: US 2010/0180865 A1
(43) Pub. Date: Jul. 22, 2010

(54) Barrier Coatings for a Piezoelectric Device

(76) Inventors: Joachim Vendulet, Niederkirchen (DE); Joachim R. Kiefer, Losheim am See (DE); Jean-Francois Berlemont, Brussels (BE)

Correspondence Address: DELPHI TECHNOLOGIES, INC;LEGAL STAFF - M/C 483-400-402, 5725 DELPHI DRIVE, PO BOX 5052, TROY, MI, 48007, US

(21) Appl. No.: 12/223,932

(22) PCT Filed: Feb. 14, 2007
(86) PCT No.: PCT/IB2007/001857

§ 371 Date: Mar. 23, 2010

(30) Foreign Application Priority Data
Feb. 14, 2006 (EP) 0602956.3
Feb. 14, 2006 (EP) 0602957.3

(51) Int. Cl. F02M 51/00; H01L 41/053; H01L 41/22

(52) U.S. Cl. 123/472; 310/340; 29/25.35

(57) ABSTRACT

Provided are barrier coatings and methods for applying barrier coatings to piezoelectric actuators that are intended for use in automotive fuel injectors. The barrier coatings are characterised by the presence of at least one organic layer, and additionally metal and/or non-metallic inorganic layers. The barrier coatings described show advantage in resisting permeation by liquid fuel, water and other contaminants.

### TECHNICAL FIELD

The invention relates to a piezoelectric device and, more particularly, to a piezoelectric device that is provided with an encapsulation means for protecting the device from the environment in which it operates. The invention has particular utility in the context of a piezoelectric device that is employed as an actuator in a piezoelectrically operated automotive fuel injector.

### BACKGROUND TO THE INVENTION

It is known to use piezoelectric actuators in fuel injectors of internal combustion engines. Such piezoelectrically operable fuel injectors provide a high degree of control over the timing of injection events within the combustion cycle and the volume of fuel that is delivered during each injection event. This permits improved control over the combustion process which is essential in order to keep pace with increasingly stringent worldwide environmental regulations. Such fuel injectors may be employed in compression ignition (diesel) engines or spark ignition (petrol) engines.

Piezoelectric actuators have been known in the field of inkjet printing for some time. Indeed, there have been attempts to encapsulate the actuator elements to protect them from atmospheric humidity and also ingress of the liquid ink. Encapsulation methods appropriate for ink jet printer use are described, for instance, in European Patent No. 0646464. However, it will be appreciated that both the overall physical structure and environment to which a piezoelectric actuator adapted for use in inkjet printing is considerably different to that of an actuator intended for use in an automotive fuel injector.

A typical piezoelectric actuator unit designed for use in an automotive fuel injector is depicted in FIG. 1. The piezoelectric actuator 10 has a stack structure formed from an alternating sequence of piezoelectric elements or layers 12 and planar internal electrodes 14. The piezoelectric layers 12, in turn, form an alternating sequence of oppositely polarised layers, and the internal electrodes 12 form an alternating sequence of positive and negative internal electrodes. The positive internal electrodes are in electrical connection with a first external electrode 16, hereinafter referred to as the positive side electrode. Likewise, the internal electrodes of the negative group are in electrical connection with a second external electrode 18, hereinafter referred to as the negative side electrode.

If a voltage is applied between the two side electrodes, the resulting electric fields between each adjacent pair of positive and negative internal electrodes cause each piezoelectric layer 12, and therefore the piezoelectric stack, to undergo a strain along its length, i.e. along an axis normal to the plane of each internal electrode 14. Because of the polarisation of the piezoelectric layers, it follows that, not only can the magnitude of the strain be controlled by adjusting the applied voltage, but also the direction of the strain can be reversed by switching the polarity of the applied voltage. Rapidly varying the magnitude and/or polarity of the applied voltage causes rapid changes in the strength and/or direction of the electric fields across the piezoelectric layers, and consequentially rapid variations in the length of the piezoelectric actuator 10. Typically, the piezoelectric layers of the stack are formed from a ferroelectric material such as lead zirconate titanate (PZT).

Such an actuator is suitable for use in a fuel injector, for example of the type known from the present Applicant's European Patent No. EP 0995901B. The fuel injector is arranged so that a change in length of the actuator results in a movement of a valve needle. The needle can be thus raised from or lowered onto a valve seat by control of the actuator length so as to permit a quantity of fuel to pass through drillings provided in the valve seat.

In use, the actuator of such a fuel injector is surrounded by fuel at high pressure. The fuel pressure may be up to or above 2000 bar. In order to protect the piezoelectric actuator from damage and potential failure, the piezoelectric actuator must be isolated from this environment by at least a layer of barrier material, herein referred to as ‘encapsulation means’. It is known to encapsulate the piezoelectric actuator with an inert fluoropolymer, for example as described in the Applicant's European published Patent Application No. EP 1356529 A, which acts to prevent permeation of liquid fuel, water and contaminant substances dissolved in the water or fuel, into the structure of the actuator. To be successful as a means of encapsulating the piezoelectric actuator, the encapsulation means must also be able to withstand fuel and water permeation over the entire operational temperature range of between around −40° C. and around 175° C.

It has been found that fluoropolymers are not completely impermeable to liquids such as diesel fuel and water. Hence, it is often a matter of time and temperature, as to when fuel or other liquids will permeate through a fluoropolymer encapsulation means leading to fatal component failure of the piezoelectric actuator and, thus, the fuel injector as a whole.

Against this background, it would be desirable to provide an encapsulating means in the form of a barrier coating having a reduced permeability to fuel, water and other substances therein.

### SUMMARY OF THE INVENTION

In a first aspect, the invention provides a piezoelectric actuator suitable for use in an automotive fuel injector, comprising a device body bearing encapsulation means to protectively encapsulate the device body wherein the encapsulation means includes at least one organic layer and at least one metal layer.

A second aspect of the invention provides a method of encapsulating a piezoelectric actuator having a device body, comprising:
applying a first organic layer to at least a part of the device body;
applying to the first organic layer a first metal layer; and
applying to the first metal layer a second organic layer;
   wherein the encapsulation provides a barrier coating that is substantially impermeable to liquid fuel and water, such that piezoelectric actuator is able to function within an automotive fuel injector.

A third aspect of the invention provides a method of encapsulating a piezoelectric actuator having a device body, comprising:
applying at least a first and a second organic layers to at least a part of the device body; and
applying to either or both of the first and second organic layers a non-metallic inorganic layer;
   wherein the encapsulation provides a barrier coating that is substantially impermeable to liquid fuel and water, such that piezoelectric actuator is able to function within an automotive fuel injector.

Further aspects of the invention provide for piezoelectric actuators that comprise barrier coatings prepared according to the methods of the invention described above.

Preferred and/or alternative features of the invention are included in the appended claims.

### BRIEF DESCRIPTION OF THE DRAWINGS

Reference has already been made to FIG. 1 that shows a perspective representation of a known piezoelectric actuator. In order for the invention to be more readily understood, embodiments of the invention will now be described, by way of example only, with reference to the remaining drawings, in which:

FIG. 2 is a part-sectional view of a portion of the actuator of FIG. 1, provided with a multilayer barrier coating according to a first embodiment of the present invention;

FIG. 3 is a part-sectional view of a portion of the actuator of FIG. 1, provided with a multilayer barrier coating according to a second embodiment of the present invention; and

FIG. 4 is a part-sectional view of a portion of the actuator of FIG. 1, provided with a multilayer barrier coating according to a third embodiment of the present invention.

### DETAILED DESCRIPTION

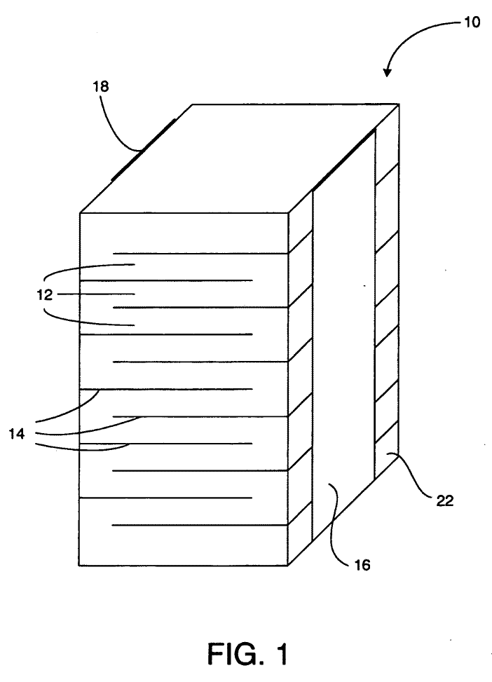

Referring to FIG. 2, in a first embodiment of the present invention, there is provided a piezoelectric actuator 10 including a piezoelectric stack, a positive side electrode 16, and a negative side electrode (not shown in FIG. 2), encapsulated with a barrier coating 20.

The piezoelectric stack comprises a plurality of piezoelectric elements or layers 12, each layer being substantially separated from its adjacent layer or layers within the stack by internal electrodes 14. The internal electrodes 14 comprise an alternating sequence of positive and negative electrodes. Each adjacent pair of positive and negative internal electrodes has disposed therebetween a respective layer 12 of piezoelectric material, which exhibits a strain in response to a voltage applied between the positive and negative internal electrodes.

Each positive internal electrode terminates at a positive face 22 of the stack, and each negative internal electrode terminates at a negative face of the stack (not shown). The positive face 22 of the stack carries the positive side electrode 16, and the negative face of the stack carries the negative side electrode 18. The positive internal electrodes are in electrical connection with the positive side electrode 16 and, likewise, the negative internal electrodes are in electrical connection with the negative side electrode 18. When the actuator is assembled, the positive and negative side electrodes are connected to a variable-voltage power source to allow control of the length of the actuator.

The barrier coating 20 comprises a layer of organic material, for example a fluoropolymer layer 24 made from ethylene tetrafluoroethylene (ETFE), which covers at least those parts of the actuator that are susceptible to exposure to fuel in use. The fluoropolymer layer 24 is carried on a surface of the actuator. The barrier layer further comprises an inorganic layer, for example a metal film 26, which is carried on the outer surface of the fluoropolymer layer 24.

The organic layer may be a fluoropolymer or other thermoplastic polymer, a polyimide, a thermoset or silicone-based organic polymer that is applied directly to the surface of the device body with the other layers applied to the first organic layer. Example of such organic layer materials are: ethylene tetrafluoroethylene (ETFE), a polytetrafluoroethylene (PTFE) thermoplastic, a polyvinyldifluoride (PVDF), a fluorinated ethylene-propylene (PEP), a perfluoroalkoxy (PFA) or a polytetrafluoroethylene-perfluoromethylvinylether (MFA).

A preferred method of forming the barrier coating of the first embodiment of the invention includes encapsulating the actuator with a layer of fluoropolymer using a heat-shrink process, for example as described in the aforementioned published European Patent Application No. EP 1356529A. It should be appreciated that the organic layer need not be applied by the heat-shrink process described above, but could be provided by any appropriate process, for example thermoplastic overmoulding.

A metal film 26 is applied to the surface of the fluoropolymer layer 24 by a physical vapour deposition (PVD) process as follows. After application to the actuator, the surface of the fluoropolymer is prepared by a series of steps, for example including cleaning, coating with a catalyst or primer and subjecting to a plasma treatment. The actuator is then disposed within a PVD chamber. The chamber is evacuated to a pressure of less than 10⁻⁴ mbar, and a quantity of the metal from which the inorganic layer is to be formed is vaporised within the chamber. Argon is injected into the chamber, and the temperature of the chamber is held below 100° C. The outer surface of the fluoropolymer layer 24 on the actuator becomes coated with a thin film of the metal, since the metal vapour is disposed to adhere to, and form the film 26 on, the prepared fluoropolymer layer surface.

An alternative method of forming the barrier coating of the invention includes encapsulating the actuator with a layer of fluoropolymer as previously described, and then using electroless plating to coat the outer surface of the fluoropolymer layer 24 with a metal to provide a metal film 26. One metal suitable for electroless plating is nickel, although any appropriate alternative metal could be used.

It is also possible to form the barrier coating of the invention by forming an inorganic layer comprising a metal film by any other appropriate polymer metallization technique. For example, an aluminum-zinc alloy film could be formed by twin-wire arc spray coating or by arc sputtering coating techniques.

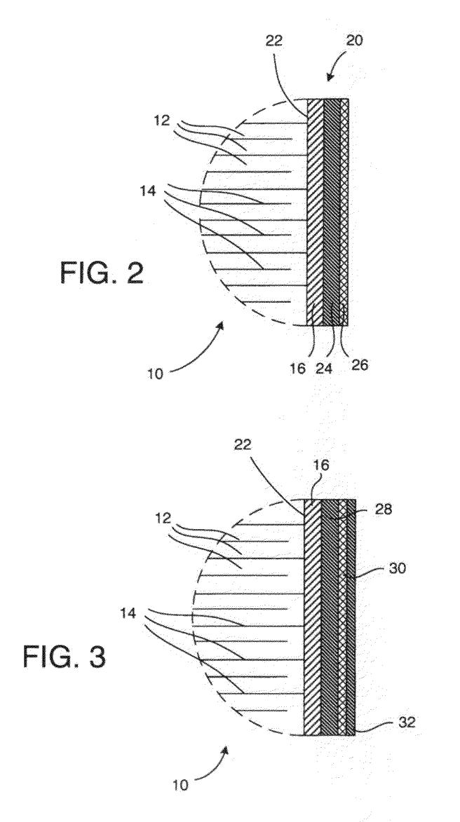

Referring to FIG. 3, in an alternative embodiment an insulating layer 28 is carried on the surface of the actuator. The insulating layer 28 is made from a polymer with a high dielectric strength, such as a polyimide (e.g. Kapton®), and acts as a passivating layer. A metal film 30 is carried on the insulating layer 28. The insulating layer 28 isolates the electrodes 14, 16, 18 and piezoelectric layers 12 of the actuator from the metal film 30. An organic layer, such as a fluoropolymer layer 32, is then carried on the metal film 30. The barrier coating therefore comprises a metal film 30 sandwiched between two layers of polymer 28, 32.

A suitable method of forming encapsulating barrier coating of the invention includes coating a polymer surface of a metallised polymer film, such as a metallised polyimide film, with a silicone-based adhesive. The metallised polymer film is then wrapped around the actuator. The adhesive coating is thus applied to the surface of the actuator, and the metallised polymer film becomes adhered to the actuator (with the adhesive in contact with the polymer). The polyimide layer of the metallised polymer film provides the insulating layer 28, and the metallised surface of the metallised polymer film provides the metal layer 30. The fluoropolymer layer 32 is then applied over the metal layer 30 as previously described. The entire surface of the metallised polymer layer may be coated with adhesive or, alternatively, only the ends or a strip of the metallised polymer film 28 may be coated with adhesive, which may be preferred in some circumstances. Still alternatively, the fluoropolymer layer 32 may be bonded to end pieces of the actuator (note shown) that may be, for example, an electrical connector of the actuator as described in the Applicants co-pending European patent application no. EP 06252352.7.

An alternative method of forming an encapsulating barrier coating of the invention includes forming the insulating layer 28 by applying an organic layer, such as a polyimide film, to the body of the actuator, then wrapping a metal film 30 around the polyimide film. The actuator, metal film and polyimide film are then encapsulated by a fluoropolymer layer 32 by a heat-shrink process as previously described. According to this method of the invention, the metal film is a self supporting substantially continuous layer of a metal or metal alloy. By “self supporting”, it is meant that the metal layer is a metal film that is capable of maintaining integrity and cohesion in isolation from the laminar encapsulation barrier composite. As such, the self supporting metal layer is typically not formed in situ via sputtering, plating or vapour deposition techniques. The metal film may include metal foil, metal leaf or metal sheet. Typically, a free standing metal foil is used having a preferred thickness of between about 1 and about 250 microns (μm), more preferably between about 5 and about 200 microns, even more preferably between about 10 and about 100 microns, most preferably between about 12 and about 30 microns. In an example of the invention, an aluminum foil having a thickness of around 20 microns is wrapped around the actuator that has already been encapsulated with a passivating organic layer 28.

Several modifications lie within the general concept of the invention. For example, the barrier film could encapsulate substantially all of the actuator, or only a part of the actuator surface. Also, although not specifically shown in FIG. 3, it should be appreciated that the barrier coating may include a further fluoropolymer layer 31, akin to the outer fluoropolymer layer 32, intermediate the metal film 30 and the passivating layer 28 in order further to improve the protective properties of the encapsulation.

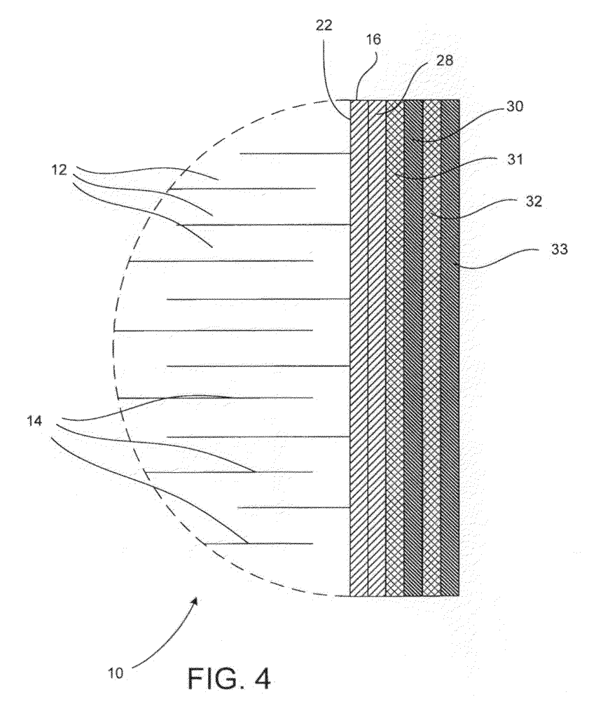

Referring to FIG. 4, an insulating layer 28 is carried on the surface of the actuator so as to cover the surface of the actuator and the electrode 16 (only one of which is shown in FIG. 4). The insulating layer 28 is secured to the actuator by way of an adhesive layer (not shown), and is made from a polymer with a high dielectric strength, such as a polyimide (e.g. Kapton®), which prevents electrical arcing across exposed edges of the internal electrodes 12, 14 of the actuator. It should be appreciated that although the insulating layer 28 is described with reference to FIG. 4 as covering the exposed ceramic surface of the actuator and the external electrodes applied to the actuator, this need not be the case and the insulating layer 28 could instead be arranged so as to cover only the exposed ceramic surface of the actuator and not the external electrodes. Preferably the adhesive layer is a silicon adhesive particularly in the form of an adhesive tape[0000] An organic fluoropolymer layer 31, as hereinbefore described, is carried on the insulating layer 28. A metal film 30, preferably aluminum foil, is carried on the first organic layer 31 radially outward of the actuator. A second organic fluoropolymer layer 32, as hereinbefore described, is carried on the metal film 30.

As a further enhancement to the encapsulation, optionally a non-metallic inorganic layer 33, such as a SiO₂ layer, is applied to and carried on the second organic fluoropolymer layer 32. In this embodiment of the invention, the non-metallic inorganic layer 33 provides high impermeability to liquid fuel, whereas the metal film 30 enhances the resistance to permeation by water and other contaminants provided by the organic layers 28 and 32.

It is preferred that the non-metallic inorganic layer is particularly impermeable to ingress of the liquid fuel in which the actuator is disposed. The present barrier encapsulation means, or barrier coatings, of the present invention are therefore improved over encapsulating means known in the art, since the actuator is better protected against contact with both fuel and other substances and so the risk of short circuits occurring is reduced.

The inorganic layer can be selected from substantially any non-metallic inorganic material. In particular: oxides, carbides, nitrides, oxyborides and oxynitrides of silicon; or oxides, carbides, nitrides, oxyborides and oxynitrides of silicon or of metals such as aluminum, zinc, indium, tin, zirconium, chromium, hafnium, thallium, tantalum, niobium and titanium are suitable.

The organic layer can also be selected from a range of suitable materials. For example, the organic layer could be an adhesive material.

The barrier coating may be multi-layered, and can comprise, for example, two or more inorganic layers separated by organic layers, or two or more organic layers

The barrier coating may be multi-layered, and can comprise, for example, two or more inorganic layers separated by organic layers, or two or more organic layers separated by inorganic layers. The second embodiment of the invention is an example of the latter case. The barrier coating could comprise substantially any number of layers, and any combination of different types of organic layers. Furthermore, several adjacent layers of metal or even non-metallic inorganic material could be provided within the barrier coating. For example, if a first applied metal layer does not provide a sufficiently low permeability, one or more additional metal layers could be applied over the first applied film. Similarly, several adjacent layers of organic material could be provided within the barrier coating, likewise several layers of non-metallic inorganic material could be incorporated.

The PVD process is particularly suited as a method of forming multiple layers of different organic and inorganic materials on the actuator. For example, an organic layer can be deposited by the PVD process by injecting gaseous monomers of a plasma-polymerizable polymer into the PVD chamber, resulting in a coating of crosslinked polymer on the surface of the actuator or an existing part-formed barrier coating. Alternatively, successive layers could be applied using different coating techniques.

The microstructure of a coating produced by PVD is dependent on a range of process parameters, including chamber pressure and temperature. Argon gas may be injected to the chamber during the PVD process in order to achieve a denser coating structure. The presence of argon modifies the trajectories of the vaporised metal atoms so that the atoms hit the surface to be coated at an increased range of incident angles. However, an alternative gas could be used in place of argon. Alternatively, gas injection might be performed. Process temperatures of up to 350° C. can be used. A selection of gas pressure, temperature and other parameters such as chamber geometry can be made to produce a desired coating microstructure.

As a further enhancement to the barrier coating, one or more non-metallic inorganic layers made from silicon oxide may be provided, in additionto, one or more metal films. For example, a silicon oxide layer may be applied on top of a fluoropolymer layer.

As mentioned above, the non-metallic inorganic layer is applied to the surface of an organic layer for the purpose of inhibiting fuel permeation into the barrier encapsulation means. In an example of the invention, the inorganic layer comprises silicon oxide and is provided using a sol-gel coating method. A liquid solution containing siloxane precursors is applied to the actuator or part-formed barrier coating. Hydrolysis and condensation processes occur to create a silicon oxide network. Functionalized monomers can be incorporated into the precursor solution in order to render the silicon oxide surface hydrophobic or to obtain anti-adhesion properties. For example, fluorine-containing siloxane monomers can be used. In addition, the precursor solution can contain nanoparticles or monomers that form nanoparticles upon film formation. The nanoparticles improve the properties of the organic-inorganic layer. The precursor solution can be applied to the bare or partially encapsulated actuator by any appropriate method, such as spraying, dipping or brushing. Curing and drying steps may then follow to polymerise the material and remove any excess solvent.

In a further enhancement, the barrier coating may also include a layer of ion exchange material in the form of a film or membrane, as described in the applicants co-pending application GB0602957.3.

The ion exchange membrane may be selected to be reactive to cations or anions and, as such, prevents the transportation of such ions across the membrane into the actuator. Cation exchange membranes typically have sulfonic acid groups attached to a polymeric backbone suitably comprising fluorinated polymers such as PTFE, ETFE, FEP or alternatively polyetherketones. Cations present in solution can enter the membrane and exchange with the protons of the acid functional groups present therein. The ion retention of the membrane is characterized by the so-called ion exchange capacity, given in meq/g. Typical ion exchange capacities for sulfonated cation exchange membranes are in the order of 2 meq/g. Ion transport is accelerated when in the presence of water by a so called ‘vehicle-mechanism’. In use, cation exchange membranes release protons, which can generate hydrogen in small quantities. Hydrogen ions are not thought to create a conductive pathway in the materials used in the construction of piezoelectric actuators. Cation-exchange membranes are mostly available in form of films or tubes. Cation-exchange membranes are suitable for retaining and exchanging cations such as K⁺, Na⁺, Ca²⁺ which are naturally dissolved in water.

On the other hand, anion exchange membranes typically contain ammonium hydroxide (NH₄OH) functional groups. Anion exchange membranes can prevent passage of anions such as chloride ions (Cl⁻), which could generate potentially harmful silver chloride (AgCl) conductive phase within the piezoelectric stack.

Higher ion exchange capacities can be achieved in crosslinked polybenzimidazole-vinylphosphonic acid (PBI-VPA) membranes. In such membranes the polymer backbone is a thermally and chemically resistant polybenzimidazole material. Ion transport and diffusion can be further controlled in this material by the amount of crosslinking—either via electrons or chemical functionalities.

As a further alternative, dual ionic exchange functionality is provided by interleaving one or more anion exchange membranes and one or more cation exchange membranes with inert ETFE polymer layers in order to build up a multilayer encapsulation assembly. The layers are bonded together using techniques known in the art of polymerics-to-polymerics bonding. The appropriate thickness for each ion exchange membrane and ETFE layer can vary between around 1 micron and around 500 microns depending on the necessary requirements of the barrier coating.

Preferably, the layer thickness for the ion exchange membranes is around 200 microns.

Dual ion exchange functionality may also be provided by a bipolar ion exchange membrane. The bipolar ion-exchange membrane comprises two layers of thermoplastic homogeneous synthetic organic polymeric material, one cationic and the other anionic, united over the whole common interface. Bipolar laminated membranes can be manufactured with both layers derived from polythene-styrene graft polymer films or glass fibre-reinforced ETFE, for example.

The invention extends to barrier coatings broadly comprising the typical sequence of first organic layer, metal layer, second organic layer. This laminar unit can be repeated one or more times if required. The first and second organic layers, as mentioned, are of polymeric composition and may be the same or may be different polymers. In a specific example of the invention in use, the first organic layer is an ETFE thermoplastic layer, the metal layer is a self supporting aluminum foil, and the second organic layer is also an ETFE thermoplastic layer. In this example, there may also be included an innermost passivation layer 28 depending on the electrical requirements of the device. The invention also extends to include a non-metallic inorganic layer that can be conveniently formed on the exterior surface of the barrier coating—i.e. on the outward facing side of the second organic layer. In another example of the invention, the first organic layer is an ETFE thermoplastic layer, the metal layer is an aluminum layer, the second organic layer is also an ETFE thermoplastic layer and the non-metallic inorganic layer is a silicon oxide layer. The combination of these layers is supra additive and provides substantially improved resistance to permeation from liquid fuel, water and other contaminants to which the actuator is exposed.

The invention is thus not limited to the configurations described above. It relates to any series and sequences of layers comprised of organic layer, metal layer or non-metallic inorganic layer. For example, the application of the non-metallic inorganic layer 33 is not limited to the exterior ETFE thermoplastic layer 32. Thus, a second or third inner inorganic layer may be applied on the inner organic layer 31 or on top of metal layer 30.

The methods for forming the barrier coating of any embodiment of the present invention could be selected as appropriate from any method previously described. Furthermore, other suitable methods could be used. A combination of methods could be used, each to form a part of the barrier coating. Standard grade electrical adhesive can suitably be used when applying the encapsulating barrier layers to the piezoelectric actuator device, which may or may not have a passivation layer already applied thereto.

It will be appreciated that the present invention is not limited in application to barrier coating of piezoelectric actuator stacks. Other electrical components could also be encapsulated with the barrier coatings without departing from the scope of the present invention.

1. A piezoelectric actuator suitable for use in an automotive fuel injector, comprising a device body bearing encapsulation means to protectively encapsulate the device body wherein the encapsulation means includes at least one organic layer and at least one metal layer.

2. The actuator of claim 1, wherein the at least one organic layer is selected from one or more of the group consisting of a thermoplastic polymer; a fluoropolymer, a polyimide; an acrylate; a silicone and an epoxy resin.

3. The actuator of claim 2, wherein the polyimide is selected from: Kapton®; Kapton®-FEP; and metallized Kapton®.

4. The actuator of claim 2, wherein the fluoropolymer comprises an ethylene tetrafluoroethylene (ETFE), a polytetrafluoroethylene (PTFE) thermoplastic, a polyvinyldifluoride (PVDF), a fluorinated ethylene-propylene (FEP), a perfluoroalkoxy (PFA) or a polytetrafluoroethylene-perfluoromethylvinylether (MFA).

5. The actuator as claimed in any preceding claim, wherein the at least one metal layer comprises a metal selected from the group consisting of: aluminum; copper; zinc; tin; nickel; gold; silver; iron; and titanium, or a metal alloy comprising one or more of the aforementioned metals.

6. The actuator as claimed in any preceding claim, wherein the at least one metal layer comprises a continuous self supporting metal film.

7. The actuator of claim 6, wherein the self supporting metal film is selected from a metal sheet; a metal leaf; and a metal foil.

8. The actuator as claimed in claim 6 or claim 7, wherein the self supporting metal film has a thickness of between about 1 and about 250 microns (μm); more preferably between about 5 and about 200 microns; even more preferably between about 10 and about 100 microns; most preferably between about 12 and about 30 microns.

9. The actuator as claimed in any preceding claim, wherein the encapsulation means further includes at least one non-metallic inorganic layer.

10. The actuator of claim 9, wherein the non-metallic inorganic layer is selected from the group consisting of an oxide; carbide; nitride; oxyboride and oxynitride of silicon, or of a metal.

11. The actuator of claim 10, wherein the metal is selected from the group consisting of aluminum; zinc; indium; tin; zirconium; chromium; hafnium; thallium; tantalum; niobium and titanium.

12. The actuator of claim 10, wherein the non-metallic inorganic layer comprises a silicon oxide.

13. The actuator as claimed in any of claims 10 to 12, wherein the non-metallic inorganic layer is applied via a sol gel process.

14. The actuator as claimed in any preceding claim, wherein the at least one metal layer is carried on the at least one organic layer, and itself carries at least one further organic layer.

15. The actuator as claimed in any preceding claim, wherein at least one of the layers included within the encapsulation means is applied via a process selected from the group consisting of: physical vapour deposition; chemical vapour deposition; sputtering; electroless plating; and overmoulding.

16. The actuator as claimed in any preceding claim, wherein the encapsulation means further includes an ion exchange membrane.

17. The actuator of claim 16, wherein the ion exchange membrane is selected to be reactive to cations.

18. The actuator of claim 16, wherein the ion exchange membrane is selected to be reactive to anions.

19. The actuator of claim 16, wherein the ion exchange membrane is a bipolar membrane.

20. The actuator of claim 19, wherein the bipolar membrane comprises laminated first and second unipolar membranes which sandwich an inert intermediate layer.

21. The actuator as claimed in any of claims 16 to 20, wherein the ion exchange membrane is homogenous.

22. The actuator as claimed in any of claims 16 to 20, wherein the ion exchange membrane is heterogeneous.

23. An automotive fuel injector provided with an encapsulated piezoelectric actuator as claimed in any of the preceding claims.

24. A method of encapsulating a piezoelectric actuator having a device body, comprising:
applying a first organic layer to at least a part of the device body;
applying to the first organic layer a first metal layer; and
applying to the first metal layer a second organic layer;
wherein the encapsulation provides a barrier coating that is substantially impermeable to liquid fuel and water, such that piezoelectric actuator is able to function within an automotive fuel injector.

25. The method of claim 24, wherein the first and second organic layers are comprised of different materials.

26. The method as claimed in claim 24 or claim 25, wherein the first and/or second organic layers comprise a material selected from one or more of the group consisting of a thermoplastic polymer; a fluoropolymer; a polyimide; an acrylate; a silicone and an epoxy resin.

27. The method of claim 26, wherein the first organic layer comprises a polyimide.

28. The method as claimed in claim 26 or claim 27, wherein the polyimide is selected from: Kapton®; Kapton®-FEP; and metallized Kapton®.

29. The method as claimed in any of claims 26 to 28, wherein the fluropolymer comprises an ethylene tetrafluoroethylene (ETFE), a polytetrafluoroethylene (PTFE) thermoplastic, a polyvinyldifluoride (PVDF), a fluorinated ethylene-propylene (FEP), a perfluoroalkoxy (PFA) or a polytetrafluoroethylene-perfluoromethylvinylether (MFA).

30. The method as claimed in any of claims 24 to 29, wherein the at least one metal layer comprises a metal selected from the group consisting of: aluminum; copper; zinc; tin; nickel; gold; silver; and titanium, or a metal alloy comprising one or more of the aforementioned metals.

31. The method as claimed in any of claims 24 to 30, wherein the at least one metal layer comprises a continuous self supporting metal film.

32. The method of claim 31, wherein the metal film is wrapped around the first organic layer.

33. The method as claimed in claim 31 or claim 32, wherein the self supporting metal film is selected from a metal sheet; a metal leaf; and a metal foil.

34. The method as claimed in any of claims 31 to 33, wherein the self supporting metal film has a thickness of between about 1 and about 250 microns (μm); more preferably between about 5 and about 200 microns; even more preferably between about 10 and about 100 microns; most preferably between about 12 and about 30 microns.

35. The method as claimed in any of claims 24 to 34, wherein the encapsulation means further includes at least one non-metallic inorganic layer.

36. The method of claim 35, wherein the at least one non-metallic inorganic layer is applied to the first organic layer before the first metal layer is applied.

37. The method of claim 35, wherein the at least one non-metallic inorganic layer is applied to the second organic layer.

38. The method as claimed in any of claims 35 to 37, wherein the non-metallic inorganic layer is selected from the group consisting of an oxide; carbide; nitride; oxyboride and oxynitride of silicon, or of a metal.

39. The method of claim 38, wherein the metal is selected from the group consisting of aluminum; zinc; indium; tin; zirconium; chromium; hafnium; thallium; tantalum; niobium and titanium.

40. The method of claim 38, wherein the non-metallic inorganic layer comprises a silicon oxide.

41. The method as claimed in any of claims 35 to 40, wherein the non-metallic inorganic layer is applied via a sol gel process.

42. The method as claimed in any of claims 24 to 41, wherein at least one of the layers included within the encapsulation means is applied via a process selected from the group consisting of: physical vapour deposition; chemical vapour deposition; sputtering; electroless plating; and overmolding.

43. The method as claimed in any of claims 24 to 42, further including the application of an ion exchange membrane.

44. The method of claim 43, wherein the ion exchange membrane is selected to be reactive to cations.

45. The method of claim 43, wherein the ion exchange membrane is selected to be reactive to anions.

46. The method of claim 43, wherein the ion exchange membrane is a bipolar membrane.

47. The method of claim 46, wherein first and second unipolar membranes are applied so as to sandwich an inert intermediate layer.

48. The method as claimed in any of claims 43 to 47, wherein the ion exchange membrane is selected to be homogenous.

49. The method as claimed in any of claims 43 to 47, wherein the ion exchange membrane is selected to be heterogeneous.

50. A piezoelectric actuator, suitable for use in an automotive fuel injector, wherein the actuator comprises a barrier coating applied according to the method of any of claims 24 to 49.

51. A method of encapsulating a piezoelectric actuator having a device body, comprising:
applying at least a first and a second organic layers to at least a part of the device body; and
applying to either or both of the first and second organic layers a non-metallic inorganic layer;
wherein the encapsulation provides a barrier coating that is substantially impermeable to liquid fuel and water, such that piezoelectric actuator is able to function within an automotive fuel injector.

52. The method of claim 51, wherein the non-metallic inorganic layer is selected from the group consisting of an oxide; carbide; nitride; oxyboride and oxynitride of silicon or, of a metal.

53. The method of claim 52, wherein the metal is selected from the group consisting of aluminum; zinc; indium; tin; zirconium; niobium and titanium.

54. The method of claim 52, wherein the non-metallic inorganic layer comprises a silicon oxide.

55. The method as claimed in any of claims 51 to 54, wherein the non-metallic inorganic layer is applied via a sol gel process.

56. The method as claimed in any of claims 51 to 55, wherein the first organic layer comprises a polyimide.

57. The method of claim 56, wherein the polyimide is selected from: Kapton®; Kapton®-FEP; and metallized Kapton®.

58. The method as claimed in any of claims 51 to 57, wherein the second organic layer comprises a material selected from the group consisting of: a thermoplastic polymer; a fluoropolymer; an acrylate; a silicone and an epoxy resin.

59. The method of claim 58, wherein the fluoropolymer is an ethylene tetrafluoroethylene (ETFE), a polytetrafluoroethylene (PTFE) thermoplastic, a polyvinyldifluoride (PVDF), a fluorinated ethylene-propylene (FEP), a perfluoroalkoxy (PFA) or a polytetrafluoroethylene-perfluoromethylvinylether (MFA).

60. The method as claimed in any of claims 51 to 59, wherein the barrier coating further comprises at least one additional layer selected from: a metal layer; a non-metal inorganic layer; and an organic layer.

61. The method as claimed in any of claims 51 to 60, wherein at least one of the layers included within the encapsulation means is applied via a process selected from the group consisting of physical vapour deposition; chemical vapour deposition; sputtering; electroless plating; and overmolding.

62. The method as claimed in any one of claims 51 to 61, further including the application of an ion exchange membrane.

63. The method of claim 62, wherein the ion exchange membrane is selected to be reactive to cations.

64. The method of claim 62, wherein the ion exchange membrane is selected to be reactive to anions.

65. The method of claim 62, wherein the ion exchange membrane is a bipolar membrane.

66. The method of claim 65, wherein the bipolar membrane comprises laminated first and second unipolar membranes which sandwich an inert intermediate layer.

67. The method as claimed in any of claims 62 to 66, wherein the ion exchange membrane is selected to be homogenous.

68. The method as claimed in any of claims 62 to 66, wherein the ion exchange membrane is selected to be heterogeneous.

69. A piezoelectric actuator, suitable for use in an automotive fuel injector, wherein the actuator comprises a barrier coating applied according to the method of any of claims 51 to 68.
